(19) United States
(12) Patent Application Publication
(10) Pub. No.: US 2010/0295162 A1
(43) Pub. Date: Nov. 25, 2010

(54) Semiconductor device

(75) Inventors: Mitsuaki Katagiri, Tokyo (JP); Hisashi Tanie, Tokyo (JP); Dai Sasaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/662,850

(22) Filed: May 6, 2010

(30) Foreign Application Priority Data
May 21, 2009 (JP) 2009-123030

(51) Int. Cl. H01L 23/495

(52) U.S. Cl. 257/676; 257/E23.031

(57) ABSTRACT

Portions of a wiring layer extending like cantilevers from an inner peripheral edge of an opening in a substrate are joined to respective terminals of a semiconductor chip mounted on the substrate. A junction portion between each portion of the wiring layer and the corresponding terminal is sealed with resin.

This application is based upon and claims the benefit of priority from Japanese patent application No. 2009-123030, filed on May 21, 2009, the disclosure of which is incorporated herein in its entirety by reference.

### BACKGROUND OF THE INVENTION

1. Field of the Invention

The present invention relates to a semiconductor device.

2. Description of the Related Art

In recent years, there has been a demand for a reduction in the thickness of DRAM packages. However, for packages having a uBGA structure in which chip terminals are connected to a tape substrate by lead bonding and packages having an sFBGA structure in which packages of the uBGA structure are stacked, the package needs to have an appropriate height for the lead bonding. Thus, the reduction in package thickness is limited. Furthermore, to allow the lead bonding to be achieved, one end of each lead needs to be projected from the tape substrate. Hence, the arrangement of wires is restricted.

FIG. 1 shows an example of a semiconductor device relating to the present invention. Semiconductor device 100 includes semiconductor chip 101, tape substrate 102, stress buffering layer 104, and sealing resin 105. Wiring layer 103a is provided on the top surface of tape substrate 102. Solder balls 107 are provided on the bottom surface of tape substrate 102. Stress buffering layer 104 is stacked on wiring layer 103a. Stress buffering layer 104 has a three-layer structure with core layer 104a and adhesion layers 104b provided on the respective opposite sides of core layer 104a. Some semiconductor devices include no stress buffering layer. However, here, the semiconductor device with the stress buffering layer will be described.

Opening 109 is formed in tape substrate 102 and stress buffering layer 104. Chip terminals 106 are provided on the bottom surface of semiconductor chip 101. Semiconductor chip 101 is stacked on adhesion layer 104b of stress buffering layer 104 so that chip terminals 106 are arranged inside opening 109. Chip terminals 106 are joined to wiring layer 103a by bonding. Specifically, wiring layer 103a is cut, and then pressed against and joined to respective chip terminals 106. The cutting and pressing of wiring layer 103a is performed using a bonding tool.

Wiring layer 103a projecting into opening 109, that is, a lead, need to be linear and to have a predetermined length before being cut. If the lead is not linear, when a load is applied to the lead using the tool in order to cut the lead, the lead is flexurally deformed and thus becomes difficult to cut. Furthermore, if the lead does not have the predetermined length, the cut lead may fail to reach the corresponding chip terminal, resulting in improper electric continuity. Furthermore, the lead that is connected to the chip terminal may undergo high tension and thus broken.

Moreover, in the above-described junction method, after wiring layer 103a is cut, unwanted parts of tape substrate 102 and stress buffering layer 104 may remain in opening 109. Thus, the semiconductor device is difficult to miniaturize in the width direction thereof.

### SUMMARY

In one embodiment, there is provided a semiconductor device that includes a substrate including a substrate which has an opening, a wiring layer formed on a principal surface of the substrate, and a plurality of extending portions which are a part of the wiring layer and which extend like cantilevers from an inner peripheral edge of the opening, a semiconductor chip which is mounted on the substrate and which has a plurality of terminals to which the respective extending portions are joined, and resin which seals a junction portion between a tip portion of each of the extending portions and the corresponding one of the terminals of the semiconductor chip.

In another embodiment, there is provided a method that includes providing a substrate which has an opening, a wiring layer formed on a principal surface of the substrate, and a plurality of extending portions which are a part of the wiring layer and which extend like cantilevers from an inner peripheral edge of the opening, mounting a semiconductor chip on the substrate, joining terminals of the semiconductor chip exposed inside the opening to the respective extending portions, and sealing a junction portion between each of the extending portions and the corresponding terminal.

### BRIEF DESCRIPTION OF THE DRAWINGS

The above feature and advantages of the present invention will be more apparent from the following description of certain preferred embodiments taken in conjunction with the accompanying drawings, in which:

FIG. 1 is a schematic side sectional view showing an example of a semiconductor device relating to the present invention;

FIG. 2A and FIG. 2B are a schematic side sectional view and a perspective plan view showing a semiconductor device according to a first exemplary embodiment;

FIG. 3 is a process diagram illustrating a method for manufacturing a semiconductor device according to the first exemplary embodiment;

FIG. 4 is a schematic side sectional view showing a semiconductor device according to a second exemplary embodiment;

FIG. 5 is a schematic perspective plan view showing a semiconductor device according to a third exemplary embodiment;

FIG. 6 is a schematic perspective plan view showing a semiconductor device according to a fourth exemplary embodiment;

FIG. 7 is a schematic perspective plan view showing a semiconductor device according to a fifth exemplary embodiment;

FIG. 8A to FIG. 8C are diagrams illustrating the principle of possible twist in an extending portion;

FIG. 9A to FIG. 9C are schematic perspective views showing an extending portion of a semiconductor device according to a sixth exemplary embodiment;

FIG. 10 is a schematic plan view showing the extending portion of the semiconductor device according to the sixth exemplary embodiment;

FIG. 11A to FIG. 11C are schematic perspective views showing a pressing mark formed on the extending portion of the semiconductor device according to the sixth exemplary embodiment;

FIG. 12 is a diagram illustrating the principle of possible twist in the extending portion;

FIG. 13 is a schematic perspective view showing an extending portion of a semiconductor device according to a seventh exemplary embodiment; and

FIG. 14 is a schematic plan view showing the extending portion of the semiconductor device according to the seventh exemplary embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### First Exemplary Embodiment

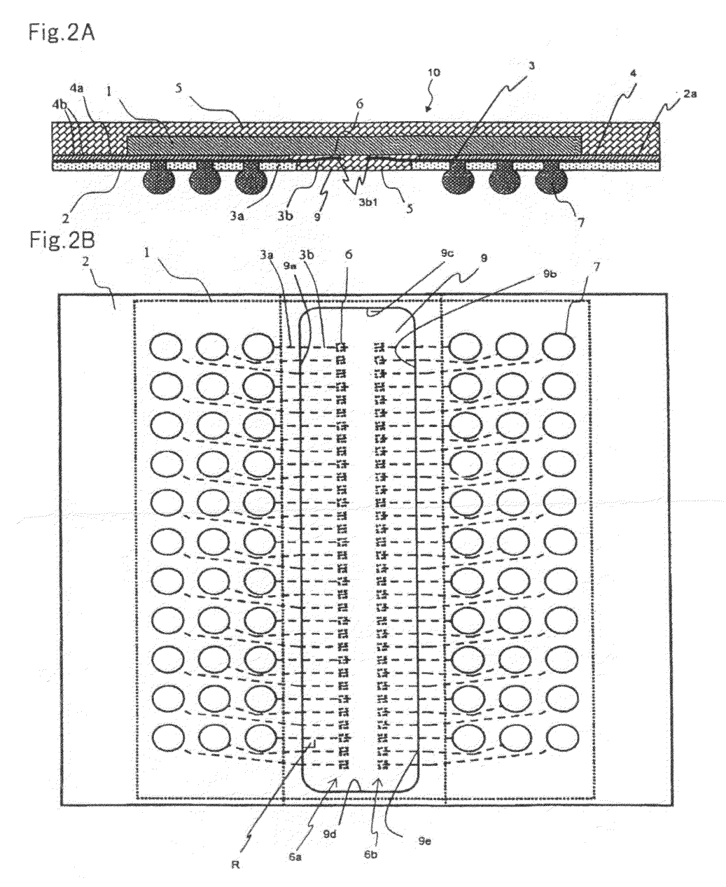

Referring now to FIG. 2A, a semiconductor device according to a first embodiment of the present invention includes semiconductor chip 1, tape substrate 2, stress buffering layer 4, and sealing resin 5 that seals semiconductor chip 1.

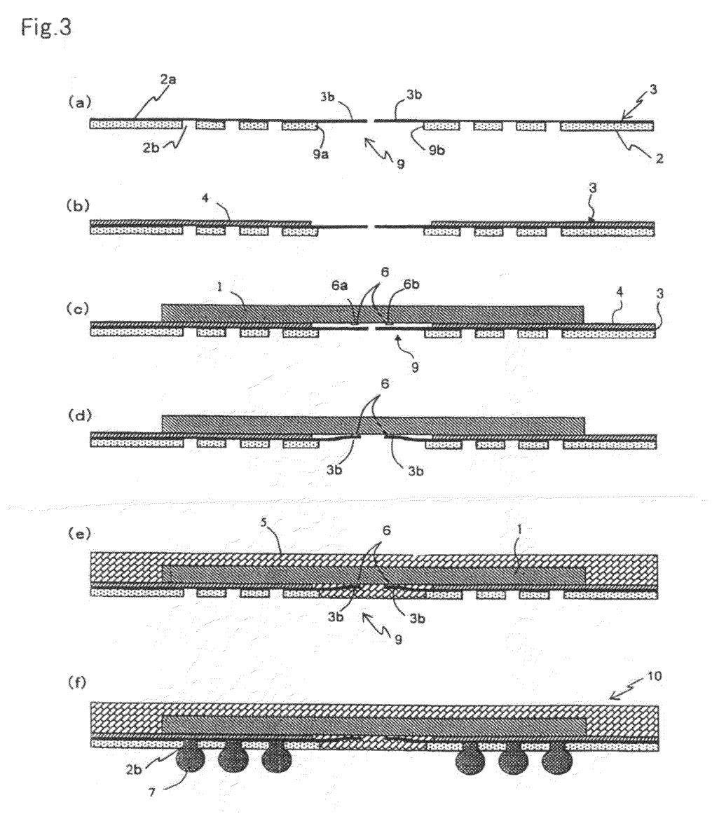

Wiring layer 3 is provided on principal surface 2a of tape substrate 2. Solder balls 7 are provided on a surface (back surface) of tape substrate 2 located opposite principal surface 2a. Wiring layer 3 provided on principal surface 2a is electrically connected to solder balls 7 provided on the back surface, via respective through-holes 2b (FIG. 3) formed in tape substrate 2.

As shown in FIG. 2B, substantially rectangular opening 9 is formed in tape substrate 2. Opening 9 includes two long sides 9a and 9b and two short sides 9c and 9d. Sides 9a to 9d form inner peripheral edges 9e of opening 9. Furthermore, only sealing resin 5 is present in opening 9.

Wiring layer 3 includes stack portion 3a stacked on tape substrate 2 and a plurality of extending portions 3b shaped like cantilevers and extending from the opposite sides of opening 9. That is, extending portions 3b form flying leads. The angle between each extending portion 3b and corresponding inner peripheral edge 9e of opening 9 is substantially a right angle. Furthermore, extending portions 3b are arranged parallel to one another. End 3b1 of each extending portion 3b (flying lead) extending like a cantilever from inner peripheral edge 9e is joined to corresponding chip terminal 6. Specifically, each extending portion 3b extending from long side 9a of opening 9 is joined to corresponding chip terminal 6 in terminal row 6a. Each extending portion 3b extending from long side 9b is joined to corresponding chip terminal 6 in terminal row 6b. That is, each extending portion 3b is joined to corresponding chip terminal 6 located close to the side from which this extending portion 3b extends. Additionally, the junction portion between end 3b1 of extending portion 3b and corresponding chip terminal 6 is sealed with sealing resin 5. Stack portion 3a of wiring layer 3 is joined to solder balls 7.

In the present embodiment, two terminal rows 6a and 6b are arranged in the center of semiconductor chip 1. Moreover, terminal rows 6a and 6b are arranged along respective long sides 9a and 9b of opening 9. However, the number and arrangement of terminal rows are not limited to those in the above-described configuration. For example, one of terminal rows 6a and 6b may be arranged in the center of semiconductor chip 1 along long sides 9a and 9b.

Stress buffering layer 4 is stacked on wiring layer 3. Stress buffering layer 4 has a three-layer structure with core layer 4a and adhesion layers 4b provided on the respective opposite sides of core layer 4a. Semiconductor chip 1 is stacked on adhesion layer 4b of stress buffering layer 4.

Now, a method for manufacturing a semiconductor device according to the exemplary embodiment will be described with reference to FIG. 3.

First, as shown in FIG. 3(a), tape substrate 2 is provided which includes opening 9, wiring layer 3 formed on principal surface 2a, plurality of extending portions 3b extending from inner peripheral edges 9a and 9b of opening 9, and through-holes 2b. As described above, extending portions 3b are a part of wiring layer 3 and extend like cantilevers from inner peripheral edges 9a and 9b of opening 9.

Next, as shown in FIG. 3(b), stress buffering layer 4 is formed on wiring layer 3. If stress buffering layer 4 is not provided, the present step is omitted.

Next, as shown in FIG. 3(c), semiconductor chip 1 is mounted on stress buffering layer 4. Semiconductor chip 1 is mounted on stress buffering layer 4 so that terminal rows 6a and 6b are arranged inside opening 9. If stress buffering layer 4 is not provided, semiconductor chip 1 is mounted on wiring layer 3.

Then, as shown in FIG. 3(d), each chip terminal 6 is joined to corresponding extending portion 3b.

Then, as shown in FIG. 3(e), semiconductor chip 1 and the inside of opening 9 is sealed with sealing resin 5. When the inside of opening 9 is sealed with sealing resin 5, the junction portion between the tip of each extending portion 3b and corresponding chip terminal 6 is sealed with sealing resin 5.

Finally, as shown in FIG. 3f, solder balls 7 are formed on respective through-holes 2b. Through the above-described steps, semiconductor device 10 according to the present embodiment is completed.

In the related art, the wiring layer which is joined to the chip terminals of the semiconductor chip is cut with a bonding tool after the semiconductor chip is mounted on the stress buffering layer. Thus, to allow the wiring layer to be cut by raising and lowering the bonding tool, the stress buffering layer needs to have a thickness of at least 100 μm. This is because the wiring layer may be improperly cut when the stress buffering layer has a thickness of less than 100 μm. Thus, reducing the thickness of the semiconductor device is limited in the related art.

On the other hand, in the manufacturing method according to the present embodiment, the wiring layer which is provided on the tape substrate is cut before semiconductor chip 1 is mounted on the tape substrate. Specifically, as shown in FIG. 3(a), wiring layer 3 is precut into pieces such that the pieces extend into opening 9 like cantilevers. This eliminates the need to increase the thickness of stress buffering layer 4 or tape substrate 2 shown in FIG. 3 in order to avoid improper cutting of wiring layer 3. That is, the manufacturing method according to the exemplary embodiment enables a reduction in the thickness of stress buffering layer 4 without being restricted by the cutting step for wiring layer 3. Moreover, the manufacturing method according to the exemplary embodiment enables stress buffering layer 4 to be omitted. Thus, the manufacturing method according to the exemplary embodiment enables a further reduction in the thickness of the semiconductor device.

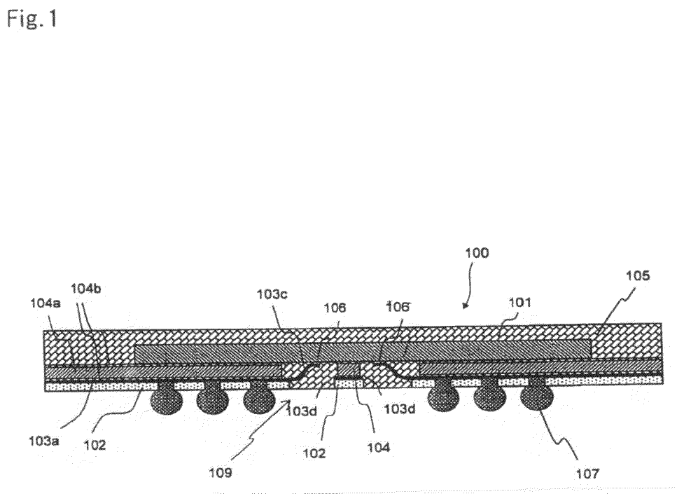

Furthermore, in semiconductor device 100 shown in FIG. 1, unwanted parts of tape substrate 102 and stress buffering layer 104 remain in opening 109. Thus, it is difficult to miniaturize semiconductor device 100 in the width direction. On the other hand, in the exemplary embodiment, as shown in FIG. 2A, tape substrate 2 and stress buffering layer 4 are present only outside opening 9. In other words, only sealing resin 5 is present inside opening 9. Hence, the exemplary embodiment enables semiconductor device 10 to be miniaturized in the width direction.

Semiconductor device structures and manufacturing methods according to exemplary embodiments described below are essentially similar to those according to the first exemplary embodiment. Thus, a detailed description of the semiconductor device structure and manufacturing method according to each exemplary embodiment is omitted. Only differences from the first exemplary embodiment will be described. Furthermore, the same members as those already described in the first exemplary embodiment are denoted by the same reference numerals.

### Second Exemplary Embodiment

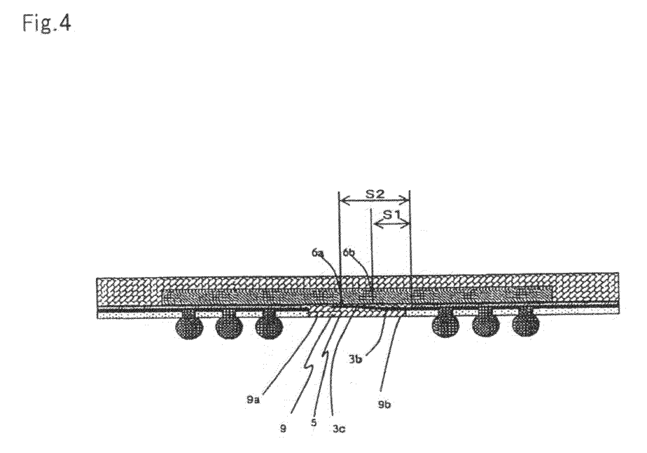

FIG. 4 is a diagram schematically showing a side cross section of a semiconductor device according to a second exemplary embodiment.

In the first exemplary embodiment, each extending portion 3b extending from long side 9a of opening 9 is joined to corresponding chip terminal 6 in terminal row 6a. Each extending portion 3b extending from long side 9b of opening 9 is joined to corresponding chip terminal 6 in terminal row 6b (FIG. 2B). Moreover, terminal row 6b shown in FIG. 2B is arranged at distance S1 from long side 9b. Terminal row 6a is arranged at distance S2 (S2>S1) from long side 9b. That is, each extending portion 3b is joined to corresponding chip terminal 6 in the terminal row located close to the side from which this extending portion 3b extends.

In the second exemplary embodiment, each extending portion 3b is joined to corresponding chip terminal 6 in terminal row 6a located far from the side from which this extending portion 3b extends. That is, each extending portion 3b extending from long side 9b of opening 9 is joined to corresponding chip terminal 6 (not shown in the drawings) in terminal row 6a arranged at distance S2 from long side 9b. Each extending portion 3b extending from long side 9a is also joined to corresponding chip terminal 6 in terminal row 6b arranged far from the side from which extending portion 3b extends. However, this is not shown in the FIG. 4.

In the related art, when leads are joined to the respective chip terminals, a bonding tool is used to cut the leads. Thus, the shape and length of the leads need to be suitable for the cutting. On the other hand, in the present invention, the preformed extending portions are joined to the respective chip terminals. Hence, as shown in FIG. 4, extending portions 3b can be joined to respective chip terminals other than those arranged closest to the side from which this extending portion 3b extends. In other words, the second exemplary embodiment allows wires to be more freely arranged.

### Third Exemplary Embodiment

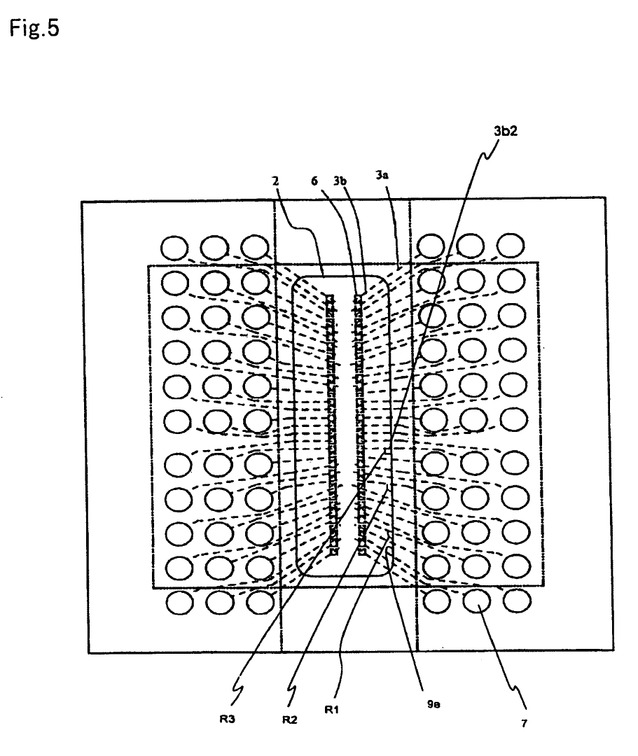

FIG. 5 is a schematic perspective plan view showing a semiconductor device according to a third exemplary embodiment.

In the first exemplary embodiment, the angle between each extending portion 3b and inner peripheral edge 9e of opening 9 is a right angle. In contrast, in the third exemplary embodiment, the angle between some extending portions 3b and inner peripheral edge 9e of opening 9 is R1. The angle between s few other extending portions 3b and inner peripheral edge 9e of opening 9 is R2. The angle between the remaining extending portions 3b and inner peripheral edge 9e of opening 9 is R3. Angles R1, R2, and R3 are different from one another. Angle R3 is a right angle. That is, extending portions 3b extend at different angles. As a result, extending portions 3b are not parallel to one another.

In the related art, a plurality of leads need to be parallel to one another so that they can be uniformly and reliably cut with the bonding tool. There is no limitation which is caused by cutting operation that uses a bonding tool. Thus, the extending portions need not be parallel to one another. This allows wires connecting solder balls 7 and chip terminal 6 shown in FIG. 5 to be more freely arranged. For example, the length of the wires connecting solder balls 7 to chip terminal 6 can be minimized. As a result, the semiconductor device can be miniaturized, and the electrical characteristics of the semiconductor device can be improved.

### Fourth Exemplary Embodiment

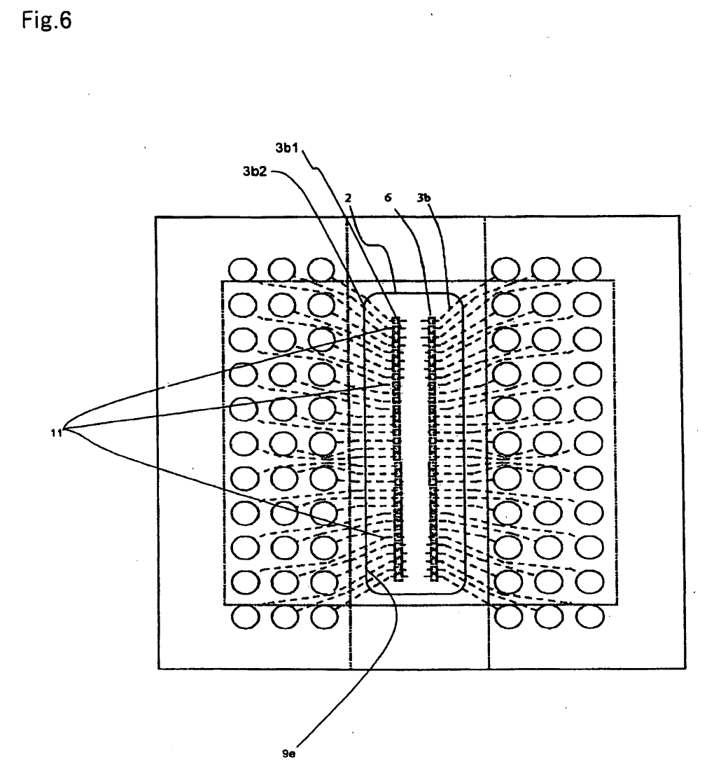

FIG. 6 is a perspective plan view showing a semiconductor device according to a fourth exemplary embodiment. In each of the above-described exemplary embodiments, each extending portion 3b extends linearly from inner peripheral edge 9e of opening 9 and is joined to corresponding chip terminal 6. On the other hand, in the fourth exemplary embodiment, extending portion 3b includes tip portion 3b1, root portion 3b2, and bent portion 11 which is located between root portion 3b2 and tip portion 3b1.

In the related art, the leads need to extend linearly into the opening so that they can be uniformly and reliably cut with the bonding tool without being flexurally deformed. There is no limitation which is caused by cutting operation that uses a bonding tool. Thus, the bent portion can be provided on the extending portion.

As described in the third exemplary embodiment, to improve the electrical characteristics, the present invention allows each extending portion to be located so as to minimize the length of the wire between the corresponding solder ball and chip terminal. However, when each extending portion is located so as to minimize the length of the wire between the corresponding solder ball and chip terminal, the adjacent extending portions may be arranged too close to each other.

Bending the extending portion 3b as shown in FIG. 6 serves to avoid excessive proximity between the extending portions 3b. As a result, the length of the wire between solder ball 7 and chip terminal 6 can be minimized with appropriate portions reliably insulated. Furthermore, the fourth exemplary embodiment enables the semiconductor device to be miniaturized similarly to the other exemplary embodiments.

### Fifth Exemplary Embodiment

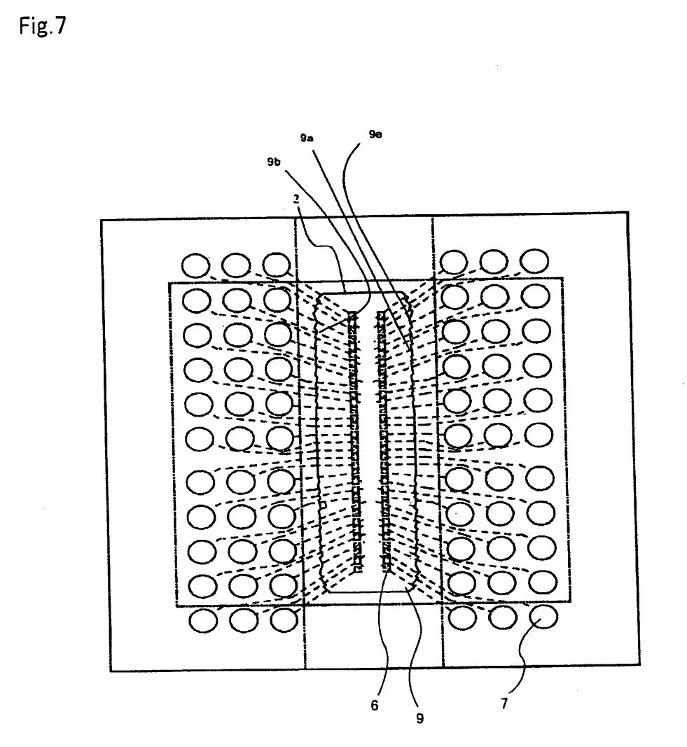

FIG. 7 is a perspective plan view showing a semiconductor device according to a fifth embodiment. In each of the above-described exemplary embodiments, long sides 9a and 9b forming inner peripheral edges 9e of opening 9 as well as short sides 9c and 9d are all linear. In the fifth exemplary embodiment, long sides 9a and 9b forming inner peripheral edges 9e of opening 9 are partly formed like saw teeth. In the saw teeth-shaped portions of long sides 9a and 9b, even if extending portion 3b is not linear, the angle between extending portion 3b and inner peripheral edge 9e of opening 9 is almost a right angle.

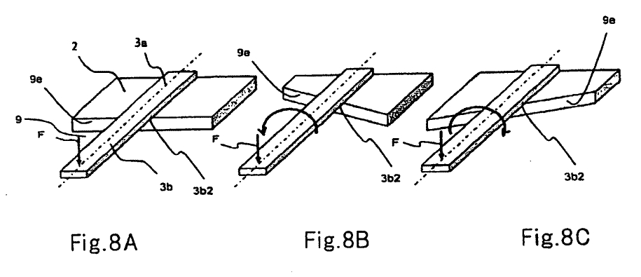

As described above in each exemplary embodiment, There is no limitation which is caused by cutting operation that uses a bonding tool. Thus, in order to improve the electrical characteristics, each wire can be formed so as to have a minimum length between the solder ball and the chip terminal. However, when only the wire length is taken into account, can the angle between the long side of the inner peripheral edge and the extending portion be an angle other than a right angle. However, to prevent the extending portion from being twisted, the angle between the long side and the extending portion is preferably as close to a right angle as possible. The principle of possible twist in extending portion 3b will be described with reference to FIG. 8.

FIG. 8A to FIG. 8C are partly enlarged perspective views of the semiconductor device according to the fifth exemplary embodiment. Extending portion 3b shown in FIG. 8A extends at an almost right angle from inner peripheral edge 9e of opening 9 in tape substrate 2. That is, the angle between extending portion 3b and inner peripheral edge 9e is almost a right angle. To allow extending portion 3b to be joined to the chip terminal (not shown in the drawings), pressing force F is applied to extending portion 3b to press extending portion 3b against the chip terminal. If the pressing force F is applied onto the center line of extending portion 3b, a uniform force is applied to root portion 3b2. Thus, extending portion 3b is difficult to twist. Here, the center line of extending portion 3b is a straight line parallel to the longitudinal direction of extending portion 3b and divides the short side of extending portion 3b in two.

On the other hand, the angle between extending portion 3b shown in FIGS. 8B and 8C and inner peripheral edge 9e is not a right angle. If pressing force F is applied onto the center line of extending portion 3b shown in FIGS. 8B and 8C, a nonuniform force is applied to root portion 3b2 to twist extending portion 3b around a longitudinal axis.

Thus, in the semiconductor device according to the fifth exemplary embodiment, as shown in FIG. 7, long sides 9a and 9b of inner peripheral edge 9e are shaped in accordance with the extending direction of each extending portion 3b so that that the angle between extending portion 3b and inner peripheral edge 9e is almost a right angle. This allows the length of the wire between solder ball 7 and chip terminal 6 to be minimized without causing a twist in extending portion 3b. Furthermore, the semiconductor device can be miniaturized.

### Sixth Exemplary Embodiment

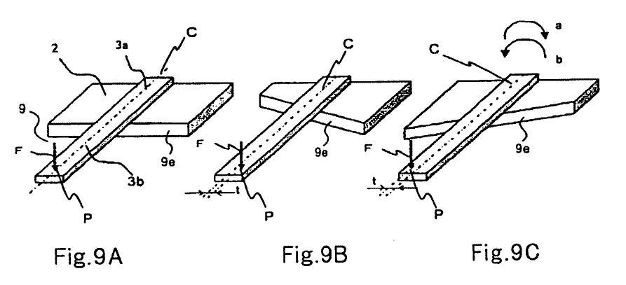

FIG. 9A to FIG. 9C are partly enlarged perspective views of a semiconductor device according to a sixth exemplary embodiment.

In the fifth exemplary embodiment, to prevent a possible twist in extending portion 3b, long sides 9a and 9b of inner peripheral edge 9e are shaped such that the angle between each extending portion 3b and inner peripheral edge 9e is almost a right angle (FIG. 7).

In the sixth exemplary embodiment, pressing force F is applied to the outside of the center line of extending portion 3b to prevent a possible twist in extending portion 3b.

Extending portion 3b shown in FIG. 9A extends at an almost right angle from inner peripheral edge 9e of opening 9 in tape substrate 2. That is, the angle between extending portion 3b and inner peripheral edge 9e is almost a right angle. No twist occurs provided that pressing force F is applied to pressing point P on center line C of extending portion 3b shown in FIG. 9A.

On the other hand, the angle between extending portion 3b shown in FIGS. 9B and 9C and inner peripheral edge 9e is not a right angle. In this case, no twist occurs provided that pressing force F is applied to pressing point P which is displaced from center line C of extending portion 3b shown in FIGS. 9B and 9C.

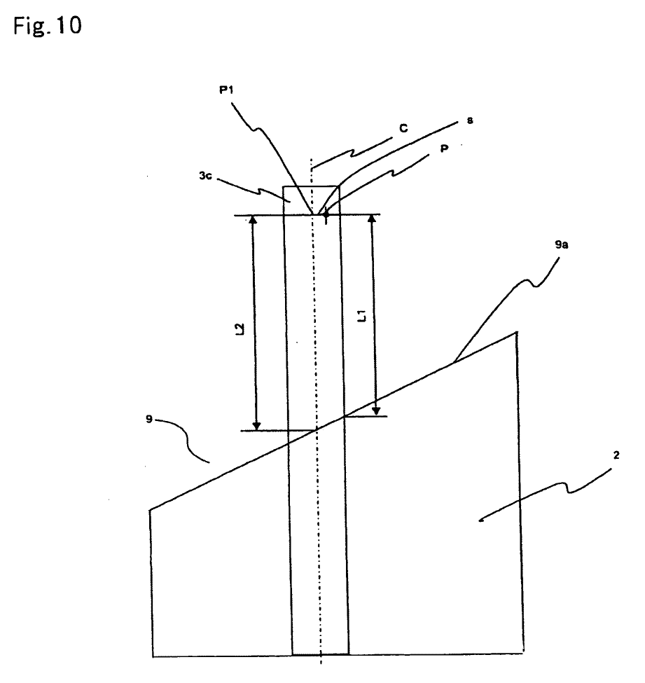

Now, the position of pressing point P will be described in further detail with reference to FIGS. 10 and 9C. The distance from pressing point P to inner peripheral edge 9e of opening 9 is defined as L1. The distance to inner peripheral edge 9e from intersection P1 of center line C with straight line S drawn from pressing point P toward center line C is defined as L2. Then, pressing point P is set at a position that satisfies relationship L1<L2.

When pressing force F is applied onto center line C of extending portion 3b shown in FIG. 9C, stress is generated which twists extending portion 3b in the direction of arrow (a). On the other hand, when pressing force F is applied to pressing point P set at a position that satisfies relationship L1<L2, stress is generated which twists extending portion 3b in the direction of arrow (b). That is, in the sixth exemplary embodiment, the two stresses offset each other to suppress twist in extending portion 3b.

If the twist in extending portion 3b is not sufficiently suppressed even by pressing the tip of extending portion 3b, pressing point P is set at a position located closest to the position where the stresses offset each other and away from the tip of extending portion 3b to the extent that bonding can be properly achieved.

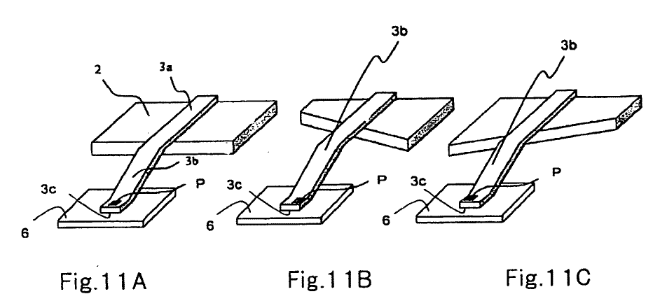

FIG. 11A to FIG. 11C are schematic perspective views showing a pressing mark (pressing point P) resulting from pressing of extending portion 3b with a bonding tool (not shown in the drawings). FIG. 11A to FIG. 11C correspond to FIG. 9A to FIG. 9C. None of extending portions 3b shown in FIG. 11A to FIG. 11C are twisted. Furthermore, abutting surface 3c of the tip of each of extending portions 3b shown in FIG. 11A to FIG. 11C is joined to a junction surface of chip terminal 6 so as to lie parallel to the junction surface.

The sixth exemplary embodiment allows the semiconductor device to be miniaturized. The sixth exemplary embodiment further allows extending portion 3b to be joined to chip terminal 6 without being twisted even if the angle between extending portion 3b and inner peripheral edge 9e is not a right angle.

### Seventh Exemplary Embodiment

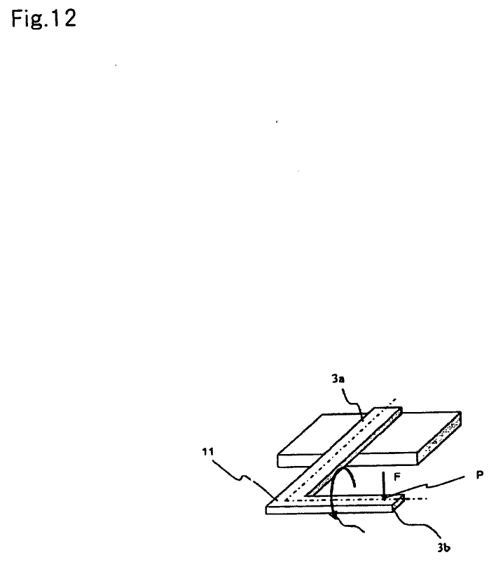

FIG. 12 is a partly enlarged perspective view of a semiconductor device according to a seventh exemplary embodiment. Extending portion 3b shown in FIG. 12 includes bent portion 11. When pressing force F is applied to the center line of extending portion 3b with bent portion 11, extending portion 3b may be twisted. FIG. 12 shows extending portion 3b with bent portion 11 folded at a right angle. However, the angle of bent portion 11 is not limited to a right angle.

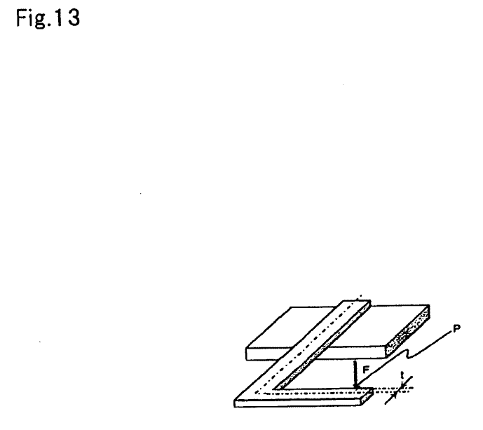

Thus, also in the seventh exemplary embodiment, a technique similar to that described in the sixth exemplary embodiment is used to suppress a twist in extending portion 3b. That is, as shown in FIG. 13, pressing point P is set at a position located off the center line of extending portion 3b. Specifically, pressing point P is set at a position where two stresses offset each other as described in the sixth exemplary embodiment.

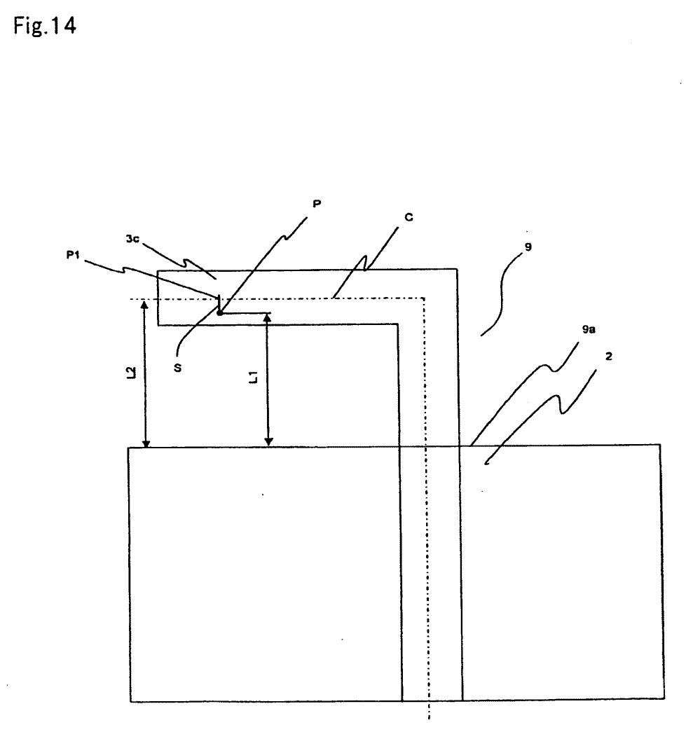

With reference to FIG. 14, the position of pressing point P will be described in detail. The distance from pressing point P to inner peripheral edge 9e of opening 9 is defined as L1. The distance to inner peripheral edge 9e from intersection P1 of center line C with straight line S drawn from pressing point P toward center line C is defined as L2. Then, pressing point P is set at a position that satisfies the relationship L1<L2.

If a twist in extending portion 3b is not sufficiently suppressed even by pressing the tip of extending portion 3b, pressing point P is set at a position located closest to the position where the stresses offset each other and away from the tip of extending portion 3b to the extent that bonding can be properly achieved.

The seventh exemplary embodiment allows the semiconductor device to be miniaturized. Furthermore, even if extending portion 3b includes bent portion 11, extending portion 3b can be joined to chip terminal 6 without being twisted.

It is apparent that the present invention is not limited to the above embodiments, but may be modified and changed without departing from the scope and spirit of the invention.

What is claimed is:

1. A semiconductor device comprising:
a substrate including an opening, a wiring layer formed on a principal surface, and a plurality of extending portions which are a part of the wiring layer and which extend like cantilevers from an inner peripheral edge of the opening;
a semiconductor chip mounted on the substrate and including a plurality of terminals to which the respective extending portions are joined; and
resin sealing a junction portion between a tip portion of each of the extending portions and the corresponding one of the terminals of the semiconductor chip.

2. The semiconductor device according to claim 1, wherein no part of the substrate is exposed on the inside of the opening.

3. The semiconductor device according to claim 1, wherein a row of the terminals is arranged in a center of the semiconductor chip along a longitudinal direction of the semiconductor chip.

4. The semiconductor device according to claim 1, wherein two rows of the terminals are arranged in a center of the semiconductor chip along a longitudinal direction of the semiconductor chip.

5. The semiconductor device according to claim 4, wherein the terminals include a first terminal located at a first distance from the inner peripheral edge and a second terminal located at a second distance from the inner peripheral edge, the second distance being longer than the first distance, and wherein the tip portion of each of the extending portions is joined to the second terminal.

6. The semiconductor device according to claim 1, wherein the extending portions extend from one corresponding inner peripheral edge from among a plurality of opposite inner peripheral edges toward the respective terminals.

7. The semiconductor device according to claim 1, further comprising a stress buffering layer located between the substrate and the semiconductor chip.

8. The semiconductor device according to claim 7, wherein the stress buffering layer has a thickness of less than 100 μm.

9. The semiconductor device according to claim 1, wherein an angle between a root portion of each of the extending portions and the corresponding inner peripheral edges is not a right angle.

10. The semiconductor device according to claim 1, wherein a bent portion is provided between the tip portion and root portion of each of the extending portions.

11. The semiconductor device according to claim 1, wherein the angle between the root portion of each of the extending portions and the corresponding inner peripheral edge is a right angle, and the angle between the inner peripheral edge and a part of the extending portion different from the root portion is not a right angle.

12. The semiconductor device according to claim 1, wherein an abutting surface between the tip portion of each of the extending portions and the corresponding terminal is parallel to each other.

13. The semiconductor device according to claim 1, wherein a pressing point, to which a pressing force is applied in order to join the tip portion of each of the extending portions to the corresponding terminal, is set at a position where at least two stresses that twist the extending portion around a center line of the extending portion are offset by each other.

14. The semiconductor device according to claim 1, wherein when a distance to the inner peripheral edge from the pressing point, to which the pressing force allowing the tip portion of each of the extending portions to be joined to the corresponding terminal is applied, is defined as a first distance and when a distance to the inner peripheral edge from an intersection of the center line of the extending portion with a straight line drawn from the pressing point toward the center line of the extending portion is defined as a second distance, the position of the pressing point is set such that the first distance is shorter than the second distance.

15. The semiconductor device according to claim 1, wherein the extending portions are formed before the semiconductor chip is mounted on the substrate.

16. A semiconductor device comprising:
a substrate including an opening, a wiring layer formed on a principal surface, and a plurality of extending portions which are a part of the wiring layer and which extend like cantilevers from an inner peripheral edge of the opening;
a semiconductor chip mounted on the substrate and including a plurality of terminals to which the respective extending portions are joined; and
resin sealing a junction portion between a tip portion of each of the extending portions and the corresponding one of the terminals of the semiconductor chip, wherein
two rows of the terminals are arranged in a center of the semiconductor chip along a longitudinal direction of the semiconductor chip, and
the extending portions extend from one corresponding inner peripheral edge from among a plurality of opposite inner peripheral edges toward the respective terminals.

17. The semiconductor device according to claim 16, wherein no part of the substrate is exposed on the inside of the opening.

18. The semiconductor device according to claim 16, wherein the terminals include a first terminal located at a first distance from the inner peripheral edge and a second terminal located at a second distance from the inner peripheral edge, the second distance being longer than the first distance, and wherein the tip portion of each of the extending portions is joined to the second terminal.

19. The semiconductor device according to claim 16, further comprising a stress buffering layer located between the substrate and the semiconductor chip.

20. The semiconductor device according to claim 19, wherein the stress buffering layer has a thickness of less than 100 μm.
